(19) United States
(12) Patent Application Publication
(10) Pub. No.: US 2023/0063001 A1
(43) Pub. Date: Mar. 2, 2023

(54) CONTROL METHOD AND SYSTEM FOR CRITICAL DIMENSION (CD)

(71) Applicant: CHANGXIN MEMORY TECHNOLOGIES, INC., Hefei City (CN)

(72) Inventors: Junjun ZHANG, Hefei City (CN); Fufang CHAO, Hefei City (CN); Zhimin WU, Hefei City (CN)

(21) Appl. No.: 17/657,819

(22) Filed: Apr. 4, 2022

(30) Foreign Application Priority Data
Aug. 30, 2021 (CN) 202111004336.1

(51) Int. Cl. H01L 21/66

(52) U.S. Cl. CPC H01L 22/20; G03F 7/70508

(57) ABSTRACT

The present disclosure provides a control method and system for a critical dimension. The control method includes: establishing a first database of a correspondence between an exposure dose of photoresist and a variation value of a critical dimension; obtaining an actual variation value of the critical dimension, and obtaining a first correction amount of the exposure dose based on the actual variation value and the first database; establishing a second database of a correspondence between waiting time between baking and development of the photoresist and the variation value of the critical dimension; presetting standard lag time between the baking and the development, obtaining actual waiting time between the baking and the development of the photoresist, and determining a time difference between the actual waiting time and the standard lag time; obtaining a compensated variation value of the critical dimension based on the time difference and the second database.

### CROSS-REFERENCE TO RELATED APPLICATION

This application claims the priority of Chinese Patent Application No. 202111004336.1, submitted to the Chinese Intellectual Property Office on Aug. 30, 2021, the disclosure of which is incorporated herein in its entirety by reference.

### TECHNICAL FIELD

The present disclosure relates to the technical field of semiconductors, and specifically, to a control method and system for a critical dimension (CD).

### BACKGROUND

During semiconductor manufacturing, photoetching is a common manufacturing process. Various device patterns and line widths can be defined through photoetching. Steps of photoetching generally include photoresist coating, post adhesion baking (PAB), alignment and exposure, post exposure baking (PEB), development, and post development baking (PDB). The quality of photoetching greatly affects performance, a yield, and the like of a semiconductor device.

With the continuous development of a very large scale integration (VLSI) circuit, a circuit is designed more complexly, a feature size is becoming smaller, and the feature size of the circuit imposes increasingly great impact on performance of a device. Photoresist is an important medium for transferring a circuit pattern to a silicon wafer. A CD of a photoresist pattern directly affects actual pattern dimensions on the silicon wafer and ultimately affects a rate of finished products. Accuracy of the CD of the photoresist pattern needs to be ensured first to ensure accuracy of an actual CD of a pattern on the silicon wafer.

An exposure dose used when a photoetching machine performs photoetching directly affects a value of the CD. The value of the CD affects actual pattern dimensions of subsequent pattern transfer and other processes, making the processes unstable and reducing a yield of a product. Therefore, it is necessary to accurately control the exposure dose based on a target CD.

It should be noted that the information disclosed above is merely intended to facilitate a better understanding of the background of the present disclosure, and therefore may include information that does not constitute the prior art known to those of ordinary skill in the art.

### SUMMARY

According to an aspect of the present disclosure, a control method for a CD is provided, wherein the control method for a CD includes:

establishing a first database of a correspondence between an exposure dose of photoresist and a variation value of a CD;

obtaining an actual variation value of the CD, and obtaining a first correction amount of the exposure dose based on the actual variation value and the first database;

establishing a second database of a correspondence between waiting time between baking and development of the photoresist and the variation value of the CD;

presetting standard lag time between the baking and the development, obtaining actual waiting time between the baking and the development of the photoresist, and

determining a time difference between the actual waiting time and the standard lag time; obtaining a compensated variation value of the CD based on the time difference and the second database;

obtaining a second correction amount of the exposure dose based on the compensated variation value and the first database;

correcting the exposure dose of the photoresist based on the first correction amount and the second correction amount; and

adjusting the CD based on a corrected exposure dose.

According to another aspect of the present disclosure, a control system for a CD is provided, wherein the control system for a CD includes:

a first database, including a correspondence between an exposure dose of photoresist and a variation value of a CD, and configured to obtain an actual variation value of the CD;

a first correction unit, wherein the first correction unit is connected to the first database and configured to obtain a first correction amount of the exposure dose based on the actual variation value and the first database;

a second database, including a correspondence between waiting time between baking and development of the photoresist and the variation value of the CD;

a time difference unit, wherein the time difference unit presets standard lag time between the baking and the development, obtains actual waiting time between the baking and the development of the photoresist, and determines a time difference between the actual waiting time and the standard lag time;

a compensation unit, wherein the compensation unit is connected to the second database and the time difference unit, and configured to obtain a compensated variation value of the CD based on the time difference and the second database;

a second correction unit, wherein the second correction unit is connected to the compensation unit and the first database, and configured to obtain a second correction amount of the exposure dose based on the compensated variation value and the first database;

a third correction unit, wherein the third correction unit is connected to the first correction unit and the second correction unit, and configured to correct the exposure dose of the photoresist based on the first correction amount and the second correction amount; and

an adjustment unit, wherein the adjustment unit is connected to the third correction unit and configured to adjust the CD based on a corrected exposure dose.

It should be understood that the above general description and the following detailed description are only exemplary and explanatory, and should not be construed as a limitation to the present disclosure.

### BRIEF DESCRIPTION OF THE DRAWINGS

The accompanying drawings incorporated into the specification and constituting a part of the specification illustrate the embodiments of the present disclosure, and are used together with the description to explain the principles of the present disclosure. Apparently, the accompanying drawings in the following description show merely some embodiments of the present disclosure, and those of ordinary skill in the art may still derive other drawings from these accompanying drawings without creative efforts. In the accompanying drawings:

FIG. 1 is a flowchart of a control method for a CD according to an embodiment of the present disclosure;

FIG. 2 is a schematic diagram of a correspondence between an exposure dose and a CD in run to run (R2R) in the related art;

FIG. 3 is a schematic diagram of a correspondence between an exposure dose and a CD according to an embodiment of the present disclosure; and

FIG. 4 is a schematic diagram of a correspondence between waiting time and a CD according to an embodiment of the present disclosure.

### DETAILED DESCRIPTION

The exemplary implementations are described more comprehensively below with reference to the accompanying drawings. However, the exemplary implementations can be implemented in various forms and should not be construed as being limited to examples described herein. On the contrary, these implementations are provided such that the present disclosure is more comprehensive and complete, and fully conveys the concept of the exemplary implementations to those skilled in the art.

The described features, structures, or characteristics may be incorporated into one or more embodiments in any suitable manner. In the following description, many specific details are provided to give a full understanding of the embodiments of the present disclosure. However, those skilled in the art will be aware that the technical solutions of the present disclosure may be practiced without one or more of the specific details, or other methods, materials, and the like may be used. In other cases, well-known method implementations or operations are not shown or described in detail to avoid obscuring aspects of the present disclosure.

The flowcharts shown in the accompanying drawings are only exemplary illustrations, and it is not mandatory to include all content and operations/steps, or perform the operations/steps in the order described. For example, some operations/steps can also be decomposed, while some operations/steps can be merged or partially merged. Therefore, an actual execution order may change based on an actual situation.

The inventors have found that an exposure dose (dose) used when a photoetching machine performs photoetching directly affects a value of a CD. In R2R, a next-lot dose is calculated based on a relative relationship (Slope) between the dose and the CD and one or more previous-lot CDs (a same lot of wafers). However, there is development lag time between a PEB process and a development process of photoresist.

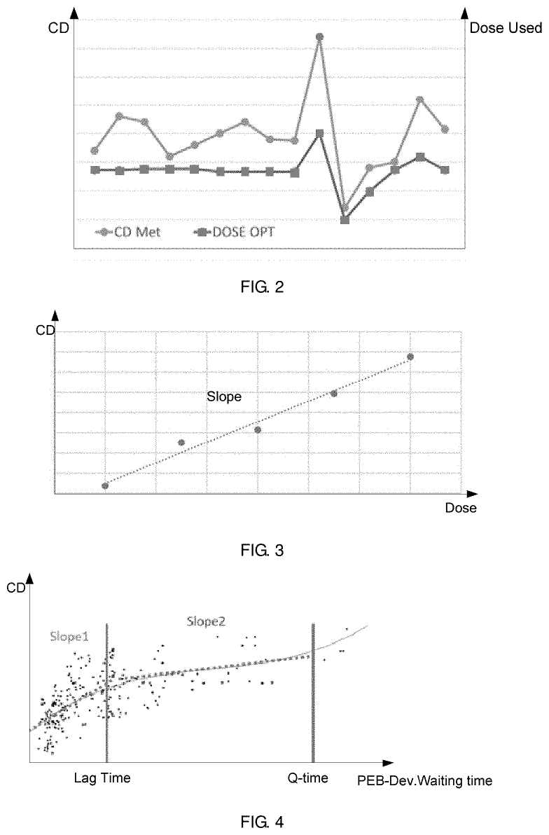

Before the development process, a photoacid concentration in an exposed region is different from that in an unexposed region, and photoacid diffusion occurs. According to the Fick's second law, a photoacid concentration at a junction between the unexposed region and the exposed region increases with time. As shown in FIG. 2, when the development lag time is too long, a value of the CD after development is affected. An abnormal CD makes a calculated Dose Opt abnormal, which further affects a next-lot dose and CD, and affects actual pattern dimensions of subsequent pattern transfer and other processes, making the processes unstable and reducing a yield of a product.

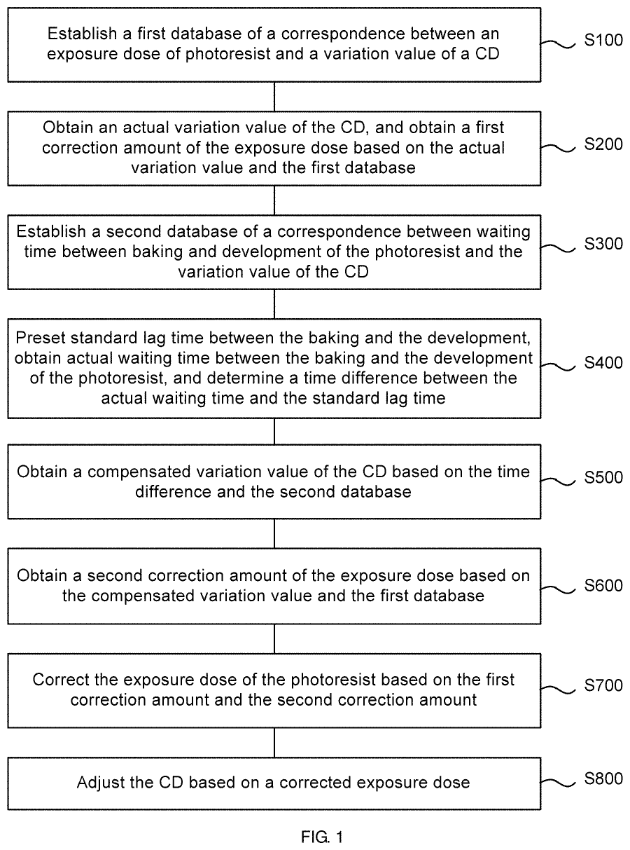

To resolve the above technical problems, an embodiment of the present disclosure provides a control method for a CD. As shown in FIG. 1, the control method for a CD includes the following steps:

Step S100: Establish a first database of a correspondence between an exposure dose of photoresist and a variation value of a CD.

Step S200: Obtain an actual variation value of the CD, and obtain a first correction amount of the exposure dose based on the actual variation value and the first database.

Step S300: Establish a second database of a correspondence between waiting time between baking and development of the photoresist and the variation value of the CD.

Step S400: Preset standard lag time between the baking and the development, obtain actual waiting time between the baking and the development of the photoresist, and determine a time difference between the actual waiting time and the standard lag time.

Step S500: Obtain a compensated variation value of the CD based on the time difference and the second database.

Step S600: Obtain a second correction amount of the exposure dose based on the compensated variation value and the first database.

Step S700: Correct the exposure dose of the photoresist based on the first correction amount and the second correction amount.

Step S800: Adjust the CD based on a corrected exposure dose.

The control method for a CD in the present disclosure establishes the first database of the correspondence between the exposure dose of the photoresist and the variation value of the CD, and establishes the second database of the correspondence between the waiting time between the baking and the development of the photoresist and the variation value of the CD; obtains the actual variation value of the CD, and obtains the first correction amount of the exposure dose based on the actual variation value and the first database; presets the standard lag time between the baking and the development, obtains the actual waiting time between the baking and the development of the photoresist, and determines the time difference between the actual waiting time and the standard lag time; obtains the compensated variation value of the CD based on the time difference and the second database; obtains the second correction amount of the exposure dose based on the compensated variation value and the first database; corrects a next-lot exposure dose of the photoresist based on the first correction amount and the second correction amount; and adjusts a next-lot CD based on a corrected dose. In this way, when development lag time is too long, a value of the CD after the development is not affected, thereby ensuring process stability and improving a yield of a product.

The steps of the control method for a CD in the present disclosure are described in detail below.

In step S100, the first database of the correspondence between the exposure dose of the photoresist and the variation value of the CD is established.

Specifically, a plurality of substrates are provided, and the photoresist is formed on each of the plurality of substrates; exposure processing is performed on the photoresist based on a target CD value and a preset exposure dose, wherein the exposure processing can be performed on the photoresist on different substrates by using different exposure doses; baking processing is performed on the photoresist on each of the plurality of substrates after first time after the exposure processing; development processing is performed after second time after the baking processing; measured CD values under different exposure doses of the photoresist are obtained, and the variation values of the CD is determined based on the measured CD values and the target CD value; and the first database of the correspondence between the exposure dose of the photoresist and the variation value of the CD is established based on the variation values and the exposure doses.

When the photoresist is positive photoresist, the CD is a CD of an etched part of the photoresist. When the photoresist is negative photoresist, the CD is a CD of a reserved part of the photoresist.

As shown in FIG. 3, that the first database of the correspondence between the exposure dose of the photoresist and the variation value of the CD is established based on the variation values and the exposure doses includes: obtaining, through fitting based on measured CD values under a plurality of groups of different exposure doses of the photoresist, a first linear correlation coefficient (Slope) between the different exposure doses of the photoresist and the measured CD values; and establishing, based on the first linear correlation coefficient, the first database of the correspondence between the exposure dose of the photoresist and the variation value of the CD.

In step S200, the actual variation value of the CD is obtained, and the first correction amount of the exposure dose is obtained based on the actual variation value and the first database.

Specifically, the actual variation value of the CD is obtained, and the first correction amount (Dose1) of the exposure dose is obtained based on the actual variation value and the first linear correlation coefficient, namely:

Dose1=(CD MET−CD target)/Slope

In the above formula, CD MET represents the measured CD value, and CD target represents the target CD value.

In step S300, the second database of the correspondence between the waiting time between the baking and the development of the photoresist and the variation value of the CD is established.

Specifically, the standard lag time and maximum lag time between the baking and the development are preset; and a second database of a correspondence between the variation value of the CD and a time period between the standard lag time and the maximum lag time is established.

The standard lag time is same waiting time between the baking and the development of the photoresist in each process, but the actual waiting time in each process is greater than the standard lag time due to the process and other reasons. The maximum lag time is longest time that can be delayed between the baking and the development of the photoresist in each process. If the actual waiting time exceeds the maximum lag time, the yield of the product may be greatly reduced.

That a second database of a correspondence between the variation value of the CD and a time period between the standard lag time and the maximum lag time is established includes: providing a plurality of substrates, and forming the photoresist on each of the plurality of substrates; performing exposure processing on the photoresist based on a target CD value and a preset exposure dose; performing baking processing after first time after the exposure processing; performing development processing after second time after the baking processing, wherein the second time is between the standard lag time and the maximum lag time; obtaining measured CD values under different second time, and determining the variation values of the CD based on the measured CD values and the target CD value; and establishing the second database of the correspondence between the variation value of the CD and the time period between the standard lag time and the maximum lag time based on the variation values and the second time.

As shown in FIG. 4, the establishing the second database of the correspondence between the variation value of the CD and the time period between the standard lag time and the maximum lag time based on the variation values and the second time includes: obtaining, through fitting based on measured CD values under a plurality of groups of different second time (PEB-Dev.Waiting time), a second linear correlation coefficient (Slope2) between the different second time and the measured CD values; and establishing the second database of the correspondence between the variation value of the CD and the time period between the standard lag time (Lag time) and the maximum lag time (Q-time) based on the second linear correlation coefficient.

Different Slope_CD_Time is obtained through region-based linear simulation. When the second time is less than the standard lag time, a third linear correlation coefficient (Slope1) between the different second time and the measured CD values is obtained through fitting. A start point of a region in which the Slope is gentle is set as the development lag time, and an end point of the region in which the Slope is gentle is set as the Q-time. For example, the lag time may be 10 min to 70 min, and the Q-time may be 3 h to 18 h. Impact of the PEB-Dev.Waiting time on the CD or Dose Opt is reduced by setting the lag time. In an R2R feedback system, the lag time is set to participate in calculation of the Dose Opt under a next-lot dose, so as to improve accuracy of the Dose Opt under the next-lot dose, and further improve a CD variation.

In step S400, the standard lag time between the baking and the development is preset, the actual waiting time between the baking and the development of the photoresist is obtained, and the time difference between the actual waiting time and the standard lag time is determined.

Specifically, the standard lag time between the baking and the development is preset, the actual waiting time between the baking and the development of the photoresist is obtained, and the time difference (Time) between the actual waiting time (Time Actual) and the standard lag time is determined, namely:

Time=Time Actual−Lag time

In the above formula, Time Actual>Lag time.

In step S500, the compensated variation value of the CD is obtained based on the time difference and the second database.

Specifically, the time difference and the second linear correlation coefficient are obtained; and the compensated variation value (CD1) of the CD is obtained based on the time difference and the second linear correlation coefficient, namely:

CD1=Time×Slope2

In step S600, the second correction amount of the exposure dose is obtained based on the compensated variation value and the first database.

Specifically, the second correction amount (Dose2) of the exposure dose is obtained based on the compensated variation value and the first database, namely:

$$Dose 2 = CD 1 / Slope$$

$$= Time \times Slope 2 / Slope$$

$$= ( Time Actual - Lag time ) \times Slope 2 / Slope$$

In step S700, the exposure dose of the photoresist is corrected based on the first correction amount and the second correction amount.

Specifically, a current exposure dose (Dose used) is obtained; and the first correction amount is subtracted from the current exposure dose, and then the second correction amount is added, to obtain the corrected exposure dose (Dose Opt), namely:

$$Dose Opt = Dose use - Dose 1 + Dose 2$$

$$= Dose use - ( CD MET - CD target ) / Slope + ( Time Actual - Lag Time ) \times Slope 2 / Slope$$

In step S800, the CD is adjusted based on the corrected exposure dose.

Specifically, the next-lot exposure dose is set based on the corrected exposure dose (Dose Opt), so as to adjust the CD. On a basis of an original feedback of a relative relationship between the CD and the dose, the present disclosure introduces the impact of the PEB-Dev.Waiting Time on the Dose Opt, so as to improve the accuracy of the Opt and improve the CD variation. This avoids a CD abnormality caused by the Time Actual. The CD abnormality makes a calculated Dose Opt abnormal, further affecting the next-lot dose and CD.

The embodiments of the present disclosure further provide a control system for a CD. The control system for a CD includes a first database, a first correction unit, a second database, a time difference unit, a compensation unit, a second correction unit, a third correction unit, and an adjustment unit.

The first database includes a correspondence between an exposure dose of photoresist and a variation value of a CD, and is configured to obtain an actual variation value of the CD; the first correction unit is connected to the first database and configured to obtain a first correction amount of the exposure dose based on the actual variation value and the first database; the second database includes a correspondence between waiting time between baking and development of the photoresist and the variation value of the CD; the time difference unit presets standard lag time between the baking and the development, obtains actual waiting time between the baking and the development of the photoresist, and determines a time difference between the actual waiting time and the standard lag time; the compensation unit is connected to the second database and the time difference unit, and configured to obtain a compensated variation value of the CD based on the time difference and the second database; the second correction unit is connected to the compensation unit and the first database, and configured to obtain a second correction amount of the exposure dose based on the compensated variation value and the first database; the third correction unit is connected to the first correction unit and the second correction unit, and configured to correct the exposure dose of the photoresist based on the first correction amount and the second correction amount; and the adjustment unit is connected to the third correction unit, and configured to adjust the CD based on a corrected exposure dose.

According to the control system for a CD in the present disclosure, the first database provides the correspondence between the exposure dose of the photoresist and the variation value of the CD, and the second database provides the correspondence between the waiting time between the baking and the development of the photoresist and the variation value of the CD; the first correction unit obtains the actual variation value of the CD, and obtains the first correction amount of the exposure dose based on the actual variation value and the first database; the time difference unit can obtain the actual waiting time between the baking and the development of the photoresist based on the preset standard lag time between the baking and the development, and determines the time difference between the actual waiting time and the standard lag time; the compensation unit can obtain the compensated variation value of the CD based on the time difference and the second database; the second correction unit can obtain the second correction amount of the exposure dose based on the compensated variation value and the first database; the third correction unit can correct a next-lot exposure dose of the photoresist based on the first correction amount and the second correction amount; and the adjustment unit can adjust a next-lot CD based on a corrected dose. In this way, when development lag time is too long, a value of the CD after the development is not affected, thereby ensuring process stability and improving a yield of a product.

Specifically, the photoresist is formed on each of a plurality of substrates; exposure processing is performed on the photoresist based on a target CD value and a preset exposure dose, wherein exposure processing can be performed on the photoresist on different substrates by using different exposure doses; baking processing is performed on the photoresist on each of the plurality of substrates after first time after the exposure processing; development processing is performed after second time after the baking processing; measured CD values under different exposure doses of the photoresist are obtained, and the variation values of the CD is determined based on the measured CD values and the target CD value; and the first database of the correspondence between the exposure dose of the photoresist and the variation value of the CD is established based on the variation values and the exposure doses. When the photoresist is positive photoresist, the CD is a CD of an etched part of the photoresist. When the photoresist is negative photoresist, the CD is a CD of a reserved part of the photoresist.

As shown in FIG. 3, based on measured CD values under a plurality of groups of different exposure doses of the photoresist, a first linear correlation coefficient (Slope) between the different exposure doses of the photoresist and the measured CD values is obtained through fitting; and the first database of the correspondence between the exposure dose of the photoresist and the variation value of the CD is established based on the first linear correlation coefficient.

Specifically, the first correction unit obtains the first correction amount (Dose1) of the exposure dose based on the actual variation value and the first linear correlation coefficient, namely:

Dose1=(CD MET−CD target)/Slope

In the above formula, CD MET represents the measured CD value, and CD target represents the target CD value.

Specifically, the time difference unit presets the standard lag time and maximum lag time between the baking and the development; and establishes a second database of a correspondence between the variation value of the CD and a time period between the standard lag time and the maximum lag time. The standard lag time is same waiting time between the baking and the development of the photoresist in each process, but the actual waiting time in each process is greater than the standard lag time due to the process and other reasons. The maximum lag time is longest time that can be delayed between the baking and the development of the photoresist in each process. If the actual waiting time exceeds the maximum lag time, the yield of the product may be greatly reduced.

The establishing a second database of a correspondence between the variation value of the CD and a time period between the standard lag time and the maximum lag time includes: forming the photoresist on each of a plurality of substrates; performing exposure processing on the photoresist based on a target CD value and a preset exposure dose; performing baking processing after first time after the exposure processing; performing development processing after second time after the baking processing, wherein the second time is between the standard lag time and the maximum lag time; obtaining measured CD values under different second time (different actual lag time between the baking processing and the development processing), and determining the variation values of the CD based on the measured CD values and the target CD value; obtaining, through fitting based on measured CD values under a plurality of groups of different second time (PEB-Dev.Waiting time), a second linear correlation coefficient (Slope2) between the different second time and the measured CD values; and establishing the second database of the correspondence between the variation value of the CD and the time period between the standard lag time (Lag time) and the maximum lag time (Q-time) based on the second linear correlation coefficient.

Different Slope_CD_Time is obtained through region-based linear simulation. When the second time is less than the standard lag time, a third linear correlation coefficient (Slope1) between the different second time and the measured CD values is obtained through fitting. A start point of a region in which the Slope is gentle is set as development lag time, and an end point of the region in which the Slope is gentle is set as the Q-time. For example, the lag time may be 10 min to 70 min, and the Q-time may be 3 h to 18 h. Impact of the PEB-Dev.Waiting time on the CD or Dose Opt is reduced by setting the lag time. In an R2R feedback system, the lag time is set to participate in calculation of the Dose Opt under a next-lot dose, so as to improve accuracy of the Dose Opt under the next-lot dose, and further improve a CD variation.

Specifically, the time difference unit presets the standard lag time between the baking and the development, obtains the actual waiting time between the baking and the development of the photoresist, and determines the time difference (Time) between the actual waiting time (Time Actual) and the standard lag time, namely:

Time=Time Actual−Lag time

In the above formula, Time Actual>Lag time.

Specifically, the compensation unit obtains the time difference and the second linear correlation coefficient; and obtains the compensated variation value (CD1) of the CD based on the time difference and the second linear correlation coefficient, namely:

CD1=Time×Slope2

Specifically, the second correction unit obtains the second correction amount (Dose2) of the exposure dose based on the compensated variation value and the first database, namely:

$$Dose 2 = CD 1 / Slope$$

$$= Time \times Slope 2 / Slope$$

$$= ( Time Actual - Lag time ) \times Slope 2 / Slope$$

Specifically, the third correction unit obtains a current exposure dose (Dose used), subtracts the first correction amount from the current exposure dose, and then adds the second correction amount, to obtain the corrected exposure dose (Dose Opt), namely:

$$Dose Opt = Dose use - Dose 1 + Dose 2$$

$$= Dose use - ( CD MET - CD target ) / Slope + ( Time Actual - Lag Time ) \times Slope 2 / Slope$$

Specifically, the adjustment unit sets the next-lot exposure dose based on the corrected exposure dose (Dose Opt), so as to adjust the CD. On a basis of an original feedback of a relative relationship between the CD and the dose, the present disclosure introduces the impact of the PEB-Dev.Waiting Time on the Dose Opt, so as to improve the accuracy of the Opt and improve the CD variation. This avoids a CD abnormality caused by the Time Actual. The CD abnormality makes a calculated Dose Opt abnormal, further affecting the next-lot dose and CD. Those skilled in the art may easily think of other implementation solutions of the present disclosure after considering the specification and practicing the content disclosed herein. The present application is intended to cover any variations, uses, or adaptive changes of the present disclosure. These variations, uses, or adaptive changes follow the general principles of the present disclosure and include common knowledge or conventional technical means in the technical field that are not disclosed by the present disclosure. The specification and the embodiments are to be regarded as exemplary only, and the true scope and spirit of the present disclosure are pointed out by the following claims.

It should be understood that the present disclosure is not limited to the precise structure that has been described above and shown in the accompanying drawings, and various modifications and changes can be made without departing from its scope. The scope of the present disclosure is defined only by the appended claims.

1. A control method for a critical dimension, comprising:
establishing a first database of a correspondence between an exposure dose of photoresist and a variation value of a critical dimension;
obtaining an actual variation value of the critical dimension, and obtaining a first correction amount of the exposure dose based on the actual variation value and the first database;
establishing a second database of a correspondence between waiting time between baking and development of the photoresist and the variation value of the critical dimension;
presetting standard lag time between the baking and the development, obtaining actual waiting time between the baking and the development of the photoresist, and determining a time difference between the actual waiting time and the standard lag time;
obtaining a compensated variation value of the critical dimension based on the time difference and the second database;
obtaining a second correction amount of the exposure dose based on the compensated variation value and the first database;
correcting the exposure dose of the photoresist based on the first correction amount and the second correction amount; and
adjusting the critical dimension based on a corrected exposure dose.

2. The control method according to claim 1, wherein the establishing a first database of a correspondence between an exposure dose of photoresist and a variation value of a critical dimension comprises:
providing a plurality of substrates, and forming the photoresist on each of the plurality of substrates;
performing exposure processing on the photoresist based on a target critical dimension value and a preset exposure dose;
performing baking processing after first time after the exposure processing;
performing development processing after second time after the baking processing;
obtaining measured critical dimension values under different exposure doses of the photoresist, and determining the variation values of the critical dimension based on the measured critical dimension values and the target critical dimension value; and
establishing, based on the variation values and the exposure doses, the first database of the correspondence between the exposure dose of the photoresist and the variation value of the critical dimension.

3. The control method according to claim 2, wherein the establishing, based on the variation values and the exposure doses, the first database of the correspondence between the exposure dose of the photoresist and the variation value of the critical dimension comprises:
obtaining, through fitting based on measured critical dimension values under a plurality of groups of different exposure doses of the photoresist, a first linear correlation coefficient between the different exposure doses and the measured critical dimension values of the photoresist; and
establishing, based on the first linear correlation coefficient, the first database of the correspondence between the exposure dose of the photoresist and the variation value of the critical dimension.

4. The control method according to claim 3, wherein the obtaining an actual variation value of the critical dimension, and obtaining a first correction amount of the exposure dose based on the actual variation value and the first database comprises:
obtaining the actual variation value of the critical dimension; and
obtaining the first correction amount of the exposure dose based on the actual variation value and the first linear correlation coefficient.

5. The control method according to claim 1, wherein the establishing a second database of a correspondence between waiting time between baking and development of the photoresist and the variation value of the critical dimension comprises:
presetting the standard lag time and maximum lag time between the baking and the development; and
establishing a second database of a correspondence between the variation value of the critical dimension and a time period between the standard lag time and the maximum lag time.

6. The control method according to claim 5, wherein the establishing a second database of a correspondence between the variation value of the critical dimension and a time period between the standard lag time and the maximum lag time comprises:
providing a plurality of substrates, and forming the photoresist on each of the plurality of substrates;
performing exposure processing on the photoresist based on a target critical dimension value and a preset exposure dose;
performing baking processing after first time after the exposure processing;
performing development processing after second time after the baking processing, wherein the second time is between the standard lag time and the maximum lag time;
obtaining measured critical dimension values under different second time, and determining the variation values of the critical dimension based on the measured critical dimension values and the target critical dimension value; and
establishing the second database of the correspondence between the variation value of the critical dimension and the time period between the standard lag time and the maximum lag time based on the variation values and the second time.

7. The control method according to claim 6, wherein the establishing the second database of the correspondence between the variation value of the critical dimension and the time period between the standard lag time and the maximum lag time based on the variation values and the second time comprises:
obtaining, through fitting based on measured critical dimension values under a plurality of groups of different second time, a second linear correlation coefficient between the different second time and the measured critical dimension values; and
establishing the second database of the correspondence between the variation value of the critical dimension and the time period between the standard lag time and the maximum lag time based on the second linear correlation coefficient.

8. The control method according to claim 7, wherein the obtaining a compensated variation value of the critical dimension based on the time difference and the second database comprises:
obtaining the time difference and the second linear correlation coefficient; and
obtaining the compensated variation value of the critical dimension based on the time difference and the second linear correlation coefficient.

9. The control method according to claim 1, wherein the correcting the exposure dose of the photoresist based on the first correction amount and the second correction amount comprises:
obtaining a current exposure dose; and
subtracting the first correction amount from the current exposure dose and then adding the second correction amount, and obtaining the corrected exposure dose.

10. The control method according to claim 1, wherein the photoresist is positive photoresist, and the critical dimension is a critical dimension of an etched part of the photoresist; or
the photoresist is negative photoresist, and the critical dimension is a critical dimension of a reserved part of the photoresist.

11. A control system for a critical dimension, comprising:
a first database, comprising a correspondence between an exposure dose of photoresist and a variation value of a critical dimension, and configured to obtain an actual variation value of the critical dimension;
a first correction unit, wherein the first correction unit is connected to the first database and configured to obtain a first correction amount of the exposure dose based on the actual variation value and the first database;
a second database, comprising a correspondence between waiting time between baking and development of the photoresist and the variation value of the critical dimension;
a time difference unit, wherein the time difference unit presets standard lag time between the baking and the development, obtains actual waiting time between the baking and the development of the photoresist, and determines a time difference between the actual waiting time and the standard lag time;
a compensation unit, wherein the compensation unit is connected to the second database and the time difference unit, and configured to obtain a compensated variation value of the critical dimension based on the time difference and the second database;
a second correction unit, wherein the second correction unit is connected to the compensation unit and the first database, and configured to obtain a second correction amount of the exposure dose based on the compensated variation value and the first database;
a third correction unit, wherein the third correction unit is connected to the first correction unit and the second correction unit, and configured to correct the exposure dose of the photoresist based on the first correction amount and the second correction amount; and
an adjustment unit, wherein the adjustment unit is connected to the third correction unit and configured to adjust the critical dimension based on a corrected exposure dose.

12. The control system according to claim 11, wherein the first database comprises a first linear correlation coefficient, obtained through fitting, between different exposure doses and measured critical dimension values of the photoresist; and the first correction unit is configured to obtain the first correction amount of the exposure dose based on the actual variation value and the first linear correlation coefficient.

13. The control system according to claim 11, wherein the second database comprises a second linear correlation coefficient, obtained through fitting, between different actual lag time between baking processing and development processing and measured critical dimension values of the photoresist; and the second correction unit is configured to obtain the compensated variation value of the critical dimension based on the time difference and the second linear correlation coefficient.

14. The control system according to claim 11, wherein the third correction unit is configured to obtain a current exposure dose, subtract the first correction amount from the current exposure dose, and then add the second correction amount, and obtain the corrected exposure dose.

15. The control system according to claim 11, wherein the photoresist is positive photoresist, and the critical dimension is a critical dimension of an etched part of the photoresist; or
the photoresist is negative photoresist, and the critical dimension is a critical dimension of a reserved part of the photoresist.
